(19) United States
(12) Patent Application Publication
(10) Pub. No.: US 2026/0310093 A1
(43) Pub. Date: Oct. 8, 2026

(54) OPERATING DEVICE AND OPERATING METHOD FOR OPTICAL PROXIMITY CORRECTION

(71) Applicant: United Microelectronics Corp., Hsinchu (TW)

(72) Inventor: Pin-Han Huang, Tainan City (TW)

(21) Appl. No.: 19/220,145

(22) Filed: May 28, 2025

(30) Foreign Application Priority Data
Apr. 2, 2025 (TW) 114112790

(51) Int. Cl. G03F 7/00

(52) U.S. Cl. CPC G03F 7/70441; G03F 7/70091

(57) ABSTRACT

An operating device is used for an optical proximity correction of a mask pattern. A mask pattern generating unit of the operating device generates the mask pattern for performing development to generate a development pattern. A development pattern evaluating unit generates a size parameter of the development pattern. A light intensity analyzing unit generates a light intensity measurement data of the development pattern. A mask pattern correcting unit calculates an actual bias of a currently processed edge of the mask pattern according to the light intensity measurement data, a step length, and the size parameters of the mask pattern and the target pattern. The mask pattern generating unit adjusts the mask pattern according to the actual bias to obtain an adjusted mask pattern. The adjusted mask pattern is used for further exposure and development to generate an adjusted development pattern.

This application claims the benefit of Taiwan application Serial No. 114112790, filed Apr. 2, 2025, the disclosure of which is incorporated by reference herein in its entirety.

### TECHNICAL FIELD

The present disclosure relates to a processing mechanism in semiconductor manufacturing, particularly to an operating device and method used for optical proximity correction of a mask pattern.

### BACKGROUND

In semiconductor manufacturing, optical lithography is often utilized to form a pattern on a mask (referred to as a ‘mask pattern’), and to perform exposure and development on a photoresist and a material to be etched using a development system.”. A light beam or electron beam may be employed to penetrate holes on the mask pattern and produce a development pattern through the exposure and development process.

However, during the exposure and development process, an optical proximity effect (OPE) may affect the development pattern obtained by the mask pattern, and hence the development pattern may not completely match the target pattern. Therefore, an optical proximity correction (OPC) is often utilized to correct and adjust the mask pattern, such that the correspondingly produced development pattern may be closer to (or approximate) the target pattern.

In a traditional optical proximity correction algorithm, it may be necessary to perform a lot of times of iterations. When the convergence speed of the iterations is low, the number of required iterations is large, which will increase the time cost required for the optical proximity correction. Furthermore, the traditional optical proximity correction algorithm cannot accurately estimate or calculate the offset that the mask pattern should be adjusted.

In view of the above issues, an improved optical proximity correction mechanism is needed, so as to improve the convergence speed of iterations and enhance the estimation accuracy of the offset of the mask pattern.

### SUMMARY

According to one embodiment of the present disclosure, an operating device is provided. The operating device is for an optical proximity correction of a mask pattern, and includes the following elements. A mask pattern generating unit, is for generating the mask pattern and a set of size parameters of the mask pattern, and generating a set of size parameters of a target pattern, and providing the mask pattern to a developing system, and the developing system performs exposure and development according to the mask pattern to generate a development pattern. A development pattern evaluating unit, is for evaluating the development pattern to generate a set of size parameters of the development pattern. A light intensity analyzing unit, is for analyzing a light intensity distribution associated with the development pattern to generate a light intensity measurement data. A mask pattern correcting unit, is for calculating an actual offset of a currently processed edge of the mask pattern according to the light intensity measurement data, a step length, the set of size parameters of the mask pattern and the set of size parameters of the target pattern, wherein the step length is a distance between a mask exterior reference point and a mask interior reference point. The mask pattern generating unit adjusts the mask pattern based on the actual offset to obtain an adjusted mask pattern. The developing system performs exposure and development again according to the adjusted mask pattern to generate an adjusted development pattern.

According to another embodiment of the present disclosure, an operating method is provided. The operating method is for an optical proximity correction of a mask pattern, and includes the following steps. Generating the mask pattern and a set of size parameters of the mask pattern, by a mask pattern generating unit. A set of size parameters of a target pattern are generated by the mask pattern generating unit, and providing the mask pattern to a developing system. Exposure and development are performed by the development system according to the mask pattern to generate a development pattern. The development pattern is evaluated to generate a set of size parameters of the development pattern, by a development pattern evaluating unit. A light intensity distribution associated with the development pattern is analyzed to generate a light intensity measurement data, by a light intensity analyzing unit. An actual offset of a currently processed edge of the mask pattern is calculated according to the light intensity measurement data, a step length, the set of size parameters of the mask pattern and the set of size parameters of the target pattern by a mask pattern correcting unit, wherein the step length is a distance between a mask exterior reference point and a mask interior reference point. The mask pattern is adjusted according to the actual offset by the mask pattern generating unit, so as to obtain an adjusted mask pattern. Exposure and development are performed again according to the adjusted mask pattern by the developing system, so as to generate an adjusted development pattern.

### BRIEF DESCRIPTION OF THE DRAWINGS

FIG. 1 is a block diagram of an operating device 1000 according to an embodiment of the present disclosure.

FIG. 2A is a schematic diagram of an example of a mask pattern MP generated by the mask pattern generating unit 100.

FIG. 2B is a schematic diagram of an example of the target pattern TP.

FIG. 2C is a schematic diagram of an example of the development pattern EP generated by the development system 2000.

FIG. 3 is a schematic diagram showing an overlap of the mask pattern MP of FIG. 2A, the target pattern TP of FIG. 2B, and the development pattern EP of FIG. 2C.

FIG. 4A is a schematic diagram showing the mask pattern MP is adjusted according to the actual offset BS_real(1).

FIG. 4B is a schematic diagram showing the developing system 2000 performs further exposure and development according to the adjusted mask pattern MP′.

FIG. 5 is a flow diagram of an operating method according to an embodiment of the present disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

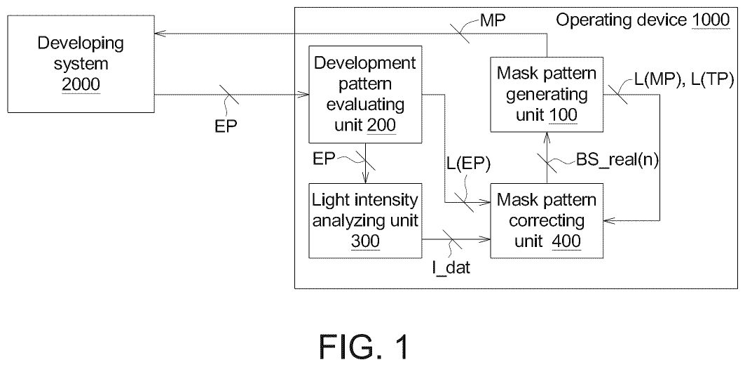

Please refer to FIG. 1, which is a block diagram of an operating device 1000 according to an embodiment of the present disclosure. The operating device 1000 is applied to a developing system 2000 of a semiconductor manufacturing process. The developing system 2000 performs exposure and development on the material to be etched, according to a mask pattern MP, so as to generate a development pattern EP. The material to be etched is, for example, a silicon substrate of a wafer or other material layers. The operating device 1000 may perform an optical proximity correction (OPC) to correct the mask pattern MP, such that the development pattern EP actually generated by the developing system 2000 can be close to (or approximate) the target pattern TP.

More specifically, the operating device 1000 includes a mask pattern generating unit 100, a development pattern evaluating unit 200, a light intensity analyzing unit 300, and a mask pattern correcting unit 400. The operating device 1000 is a hardware circuit installed in a semiconductor manufacturing machine, and the mask pattern generating unit 100, the development pattern evaluating unit 200, the light intensity analyzing unit 300 and the mask pattern correcting unit 400 are hardware circuit units inside the operating device 1000. The mask pattern generating unit 100 is a hardware circuit in a mask pattern manufacturing device commonly used in semiconductor processes, and is capable of analyzing parameters of the mask pattern. The development pattern evaluating unit 200 is also a hardware circuit, which can perform detailed analysis on the development pattern on the material to be etched, in the semiconductor device, so as to obtain the parameters of the development pattern. The light intensity analyzing unit 300 is a hardware circuit with optical analysis capability, and can analyze optical characteristics associated with the development pattern on the material to be etched (e.g., the light transmittance and light intensity distribution of etched portions of through-holes of the development pattern).

In one example, the mask pattern correcting unit 400 is a hardware circuit with high computing power, such as a hardware processor which may include a digital signal processor (DSP), a central processing unit (CPU), and a micro control unit (MCU), etc., but not limited to these. In another example, the mask pattern correcting unit 400 is implemented as a software program module, and various operations of the mask pattern correcting unit 400 are implemented by executing internal software code (the software code comprises multiple instructions) through a hardware processor (e.g., the digital signal processor, the central processing unit, or the micro control unit) or a hardware device (e.g., a controller, a computer device, or a computer). The software codes mentioned above, may be stored in a non-transitory computer-readable storage medium. The non-transitory computer-readable storage medium is, for example, various forms of non-transitory (non-volatile) memories, hard disk, USB flash drive and other storage devices. When the hardware processor or the hardware device reads the software code from the non-transitory computer-readable storage medium, the hardware processor or the hardware device may execute the instructions in the software code to perform various operations of the mask pattern correcting unit 400.

More specifically, the mask pattern generating unit 100 is used to generate the mask pattern MP, and provide the mask pattern MP to the developing system 2000. The developing system 2000 generates a development pattern EP according to the mask pattern MP, and provides the development pattern EP to the development pattern evaluating unit 200. The development pattern evaluating unit 200 evaluates the development pattern EP, so as to obtain a set of size parameters L(EP) of the development pattern EP. Also, the development pattern evaluating unit 200 provides the size parameter L(EP) of the development pattern EP to the mask pattern correcting unit 400.

The development pattern evaluating unit 200 provides the development pattern EP to the light intensity analyzing unit 300. The light intensity analyzing unit 300 analyzes the light intensity distribution I(EP) associated with the development pattern EP, and generates light intensity measurement data I_dat according to the light intensity distribution I(EP). The light intensity analyzing unit 300 provides the light intensity measurement data I_dat to the mask pattern correcting unit 400.

The mask pattern generating unit 100 analyzes the mask pattern MP and the target pattern TP, so as to obtain a set of size parameters L(MP) of the mask pattern MP and a set of size parameters L(TP) of the target pattern TP. Furthermore, the mask pattern generating unit 100 provides the size parameter L(MP) of the mask pattern MP and the size parameter L(TP) of the target pattern TP to the mask pattern correcting unit 400.

The mask pattern correcting unit 400 generates an offset BS according to the size parameter L(MP) of the mask pattern MP, the size parameter L(TP) of the target pattern TP, and the light intensity distribution I(EP) and size parameter L(EP) associated with the development pattern EP, and provides the offset BS to the mask pattern generation unit 100. The mask pattern generating unit 100 adjusts the mask pattern MP according to the offset BS. Furthermore, the mask pattern generating unit 100 provides an adjusted mask pattern MP′ to the developing system 2000. The developing system 2000 generates an adjusted development pattern EP′ according to the adjusted mask pattern MP′.

According to the above embodiment, the operating device 1000 performs several times of adjustments on the mask pattern MP through several iterations, so that the development pattern EP generated by the development system 2000 can be close to the target pattern TP.

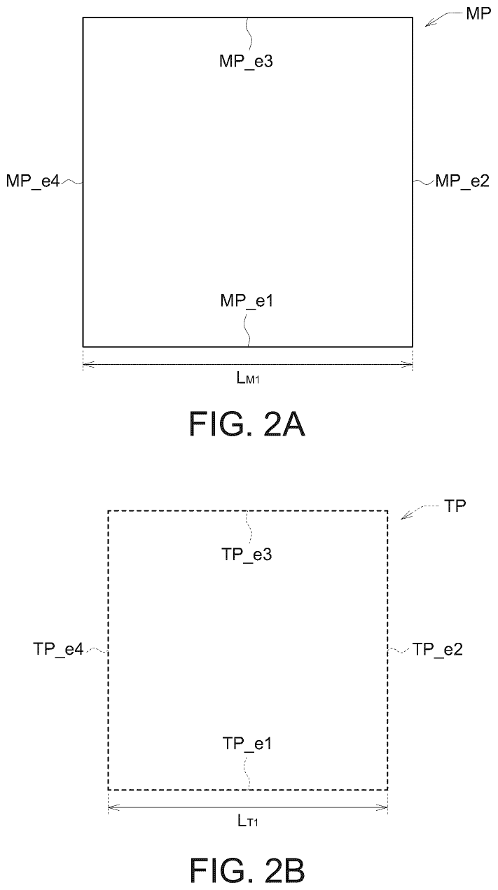

FIG. 2A is a schematic diagram of an example of a mask pattern MP generated by the mask pattern generating unit 100. The mask pattern MP may be a polygon. In the embodiment of FIG. 2A, the mask pattern MP is, for example, a quadrilateral. The mask pattern MP has an edge MP_e1, an edge MP_e2, an edge MP_e3, and an edge MP_e4. These edges MP_e1~MP_e4 have respective lengths. Taking the edge MP_e1 as an example, the edge MP_e1 has a length L_{M1}. Furthermore, the mask pattern generating unit 100 integrates relevant dimensions of the mask pattern MP (e.g., the respective lengths of the edges MP_e1~MP_e4) into the size parameter L(MP) of the mask pattern MP.

FIG. 2B is a schematic diagram of an example of the target pattern TP. The target pattern TP may be a polygon. In the embodiment of FIG. 2B, the target pattern TP is, for example, a quadrilateral. The target pattern TP has an edge TP_e1, an edge TP_e2, an edge TP_e3, and an edge TP_e4. These edges TP_e1~TP_e4 have respective lengths. Taking the edge TP_e1 as an example, the edge TP_e1 has a length LT1. Furthermore, the mask pattern generating unit 100 integrates relevant dimensions of the target pattern TP (e.g., respective lengths of the edges TP_e1~edge TP_e4) into the size dimension parameter L(TP) of the target pattern TP. The mask pattern generating unit 100 provides the size parameter L(MP) of the mask pattern MP and the size parameter L(TP) of the target pattern TP to the mask pattern correcting unit 400.

FIG. 2C is a schematic diagram of an example of the development pattern EP generated by the development system 2000. The development pattern EP is generated by the development system 2000 through exposure and development, according to the mask pattern MP of FIG. 2A. The development pattern EP is, for example, approximately circular; and the development pattern EP has a periphery EP_e.

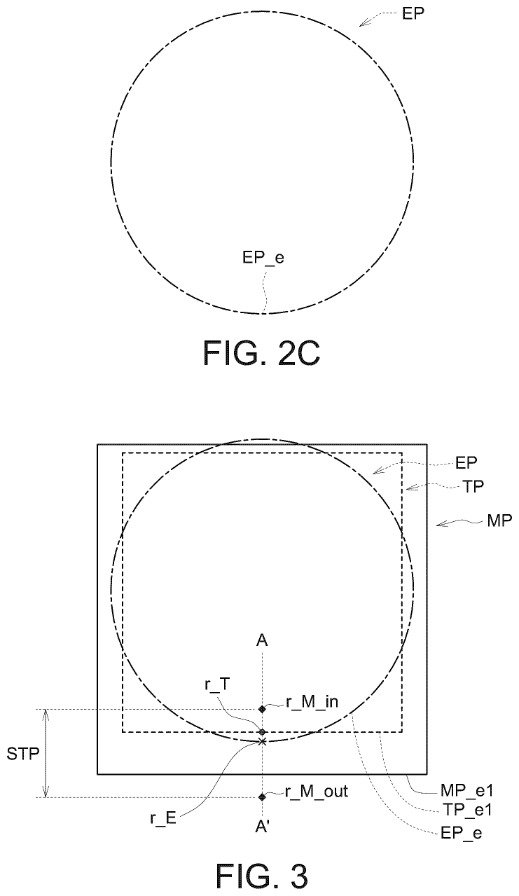

FIG. 3 is a schematic diagram showing an overlap of the mask pattern MP of FIG. 2A, the target pattern TP of FIG. 2B, and the development pattern EP of FIG. 2C. The mask pattern correcting unit 400 defines an inside and an outside of the mask pattern MP, according to the four edges MP_e1~MP_e4 of the mask pattern MP. Taking the edge MP_e1 as an example, the mask pattern correcting unit 400 uses the edge MP_e1 as a boundary, where the portion outside the edge MP_e1 is defined as the outside of the mask pattern MP, and the portion inside the edge MP_e1 is defined as the inside of the mask pattern MP. The mask pattern correcting unit 400 sets a reference point r_M_in and a reference point r_M_out inside and outside the mask pattern MP, respectively. In other words, the reference point r_M_in and the reference point r_M_out are respectively located at the inner side and the outer side of the edge MP_e1 of the mask pattern MP. The reference point r_M_out may also be referred to as a “mask exterior reference point”, and the reference point r_M_in may also be referred to as a “mask interior reference point”. The distance between the reference point r_M_out and the reference point r_M_in is defined as a step length STP.

The mask pattern correcting unit 400 defines a reference line AA′ according to the reference point r_M_in and the reference point r_M_out. The reference line AA′ passes through the reference point r_M_out and the reference point r_M_in. Furthermore, the mask pattern correcting unit 400 sets a reference point r_T and a reference point r_E according to the reference line AA. The reference point r_T is an intersection of the reference line AA′ and the edge TP_e1 of the target pattern TP (also referred to as the “target edge reference point”), and the reference point r_E is an intersection of the reference line AA′ and the periphery EP_e of the development pattern EP (also referred to as a “development periphery reference point”).

The light intensity analyzing unit 300 analyzes the optical characteristics associated with the development pattern EP, so as to obtain a light intensity distribution I(EP) associated with the development pattern EP. Furthermore, the light intensity analyzing unit 300 obtains the light intensity distribution I(AA′) associated with the reference line AA′ according to the light intensity distribution I(EP).

Furthermore, according to the light intensity distribution I(AA′) associated with the reference line AA′, the light intensity analyzing unit 300 obtains respective light intensities corresponding to the reference points r_M_in, r_M_out, r_T and r_E. More particularly, the reference point r_M_in has a light intensity Iᵢₙ, the reference point r_M_out has a light intensity Iₒᵤₜ, the reference point r_T has a light intensity I_{T}, and the reference point r_E has a light intensity I_{E}.

The light intensity analyzing unit 100 integrates the light intensity Iᵢₙ, the light intensity Iₒᵤₜ, the light intensity I_{T} and the light intensity I_{E} into a light intensity measurement data I_dat. Furthermore, the light intensity analyzing unit 100 provides the light intensity measurement data I_dat to the mask pattern correcting unit 400.

According to the light intensity measurement data I_dat, the step length STP, the size parameter L(MP) of the mask pattern MP and the size parameter L(TP) of the target pattern TP, the mask pattern correcting unit 400 calculates a preliminary offset BS(1) according to equation (1-1):

$$BS ( 1 ) = \frac{( {I}_{E} - {I}_{T} ) \times S T P}{\vert {I}_{i n} - {I}_{o u t} \vert} \times {( \frac{{L}_{T 1}}{{L}_{M 1}} )}^{2} = W 1 \times S T P \times W 2 \qquad ( 1 - 1 )$$

$$W 1 = \frac{( {I}_{E} - {I}_{T} )}{\vert {I}_{i n} - {I}_{o u t} \vert} \qquad ( 1 - 2 )$$

$$W 2 = {( \frac{{L}_{T 1}}{{L}_{M 1}} )}^{2} \qquad ( 1 - 3 )$$

In equation (1-1), the mask pattern correcting unit 400 calculates a light intensity difference between the reference point r_E and the reference point r_T (i.e., a difference value (I_{E}−I_{T}) between the light intensity I_{E} and the light intensity I_{T}). Furthermore, the absolute light intensity difference between the reference point r_M_in and the reference point r_M_out is calculated, which is an absolute difference |Iᵢₙ−Iₒᵤₜ| between the light intensity Iᵢₙ and the light intensity Iₒᵤₜ. Furthermore, the mask pattern correcting unit 400 uses a ratio of the difference (I_{E}−I_{T}) with respect to the absolute difference |Iᵢₙ−Iₒᵤₜ| as the first weight W1. The step length STP multiplied by the first weight W1 is the estimated distance between the reference point r_E and the reference point r_T.

On the other hand, the mask pattern correcting unit 400 calculates a ratio

$$( \frac{{L}_{T 1}}{{L}_{M 1}} )$$

of the length LT1 of an edge TP_e1 of the target pattern TP and the length LM1 of an edge MP_e1 of the mask pattern MP. The mask pattern correcting unit 400 uses a square of the ratio

$$( \frac{{L}_{T 1}}{{L}_{M 1}} )$$

as the second weight W2, and adjusts the estimated distance between the reference point r_E and the reference point r_T by the second weight W2, so as to obtain a preliminary offset BS(1).

The preliminary offset BS(1) is obtained by considering one edge TP_e1 of the target pattern TP and the corresponding edge MP_e1 of the mask pattern MP. However, other factors of the adjacent edges of the target pattern TP and the mask pattern MP still need to be considered. Therefore, the mask pattern correcting unit 400 calculates an offset weighted sum BS_SUM of adjacent edges, as shown in equation (2-1):

$$BS\_SUM = \vert {\sum }_{k = n - r}^{n + r} {C}_{k} [ {( \frac{{L}_{k}}{{L}_{n}} )}^{2} \times B S ( k ) ] \vert \qquad ( 2 - 1 )$$

In equation (2-1), the index n represents the “current processing edge”, that is, the corresponding n-th edge MP_e(n) of the mask pattern MP. The currently processed edge represented by the index n has a length Ln.

Furthermore, an adjacent edge of the currently processed edge is represented by index k, and the adjacent edge represented by index k has a length Lₖ. The range of index k is from (n−r) to (n+r). That is, the adjacent edge represented by the index k include the edge MP_e(n−r) to the edge MP_e(n+r) of the mask pattern MP.

Taking the mask pattern MP and the target pattern TP in FIGS. 2A and 2B as examples, both of them are quadrilaterals, and the value r in equation (2-1) is equal to “1”. In the embodiments of FIGS. 2A and 2B, the currently processed edge is the edge MP_e1 of the mask pattern MP, and the adjacent edges include the edge MP_e4 and the edge MP_e2 of the mask pattern MP. Furthermore, the edge TP_e1 of the target pattern TP corresponds to the edge MP_e1 of the mask pattern MP, and the edge TP_e1 may be referred to as a “first edge”. In other words, the “first edge” of the target pattern TP corresponds to the current processing edge of the mask pattern MP.

The adjacent edge represented by the index k corresponds to the offset BS(k). In the previous iteration, the mask pattern correcting unit 400 has calculated the offset BS(k) corresponding to the index k. In equation (2-1), the absolute value of the weighted sum of the offsets BS(k) corresponding to all index k ranging from (n−r) to (n+r) is the offset weighted sum BS_SUM.

Furthermore, the mask pattern correcting unit 400 calculates the ratio of the offset weighted sum BS_SUM with respect to the absolute value of the preliminary offset BS(n) of the currently processed edge, so as to obtain a third weight W3, as shown in equations (2-2) or (2-3). Taking the mask pattern MP in FIG. 2A as an example, the currently processed edge is edge MP_e1, and the preliminary offset BS(n) of the currently processed edge is the preliminary offset BS(1) shown in equation (1-1).

$$W 3 = \frac{BS\_SUM}{\vert BS ( n ) \vert} \qquad ( 2 - 2 )$$

$$W 3 = \frac{\vert BS ( n ) \vert}{BS\_SUM} \qquad ( 2 - 3 )$$

The mask pattern correcting unit 400 analyzes whether the offset weighted sum BS_SUM and the preliminary offset BS(n) of the current processing edge are equal to “0”, and further analyzes the signs (i.e., positive or negative) of the offset weighted sum BS_SUM and the preliminary offset BS(n) of the current processing edge. Then, setting or calculating the value of the third weight W3 according to the above analysis results.

When the sign of the preliminary offset BS(n) is opposite to the sign of the offset weighted sum BS_SUM (i.e., different signs), the third weight W3 is the ratio shown in equation (2-2), and the value of the third weight W3 is greater than “1”.

On the other hand, when the sign of the preliminary offset BS(n) is the same as the sign of the offset weighted sum BS_SUM (i.e., the same sign), the third weight W3 is the ratio shown in equation (2-3), and the value of the third weight W3 is between “0” and “1”.

Furthermore, when the preliminary offset BS(n) or the offset weighted sum BS_SUM is equal to “0”, the mask pattern correcting unit 400 forces to set the third weight W3 to “1”.

Then, the mask pattern correcting unit 400 multiplies the third weight W3 of equations (2-2) or (2-3) (or the value of the third weight W3 is equal to “1”) by the preliminary offset BS(n) of the current processing edge, so as to obtain an actual offset BS_real(n) of the current processing edge, as shown in equation (2-4):

$$BS\_real = W 3 \times B S ( n ) \qquad ( 2 - 4 )$$

Furthermore, the mask pattern correcting unit 400 sends the actual offset BS_real(n) to the mask pattern generation unit 100. The mask pattern generating unit 100 adjusts the mask pattern MP according to the actual offset BS_real(n).

Taking the mask pattern MP of FIG. 2A as an example, the currently processed edge is edge MP_e1. The mask pattern correcting unit 400 calculates the actual offset BS_real(1) of the edge MP_e1. The mask pattern generating unit 100 adjusts the mask pattern MP according to the actual offset BS_real(1).

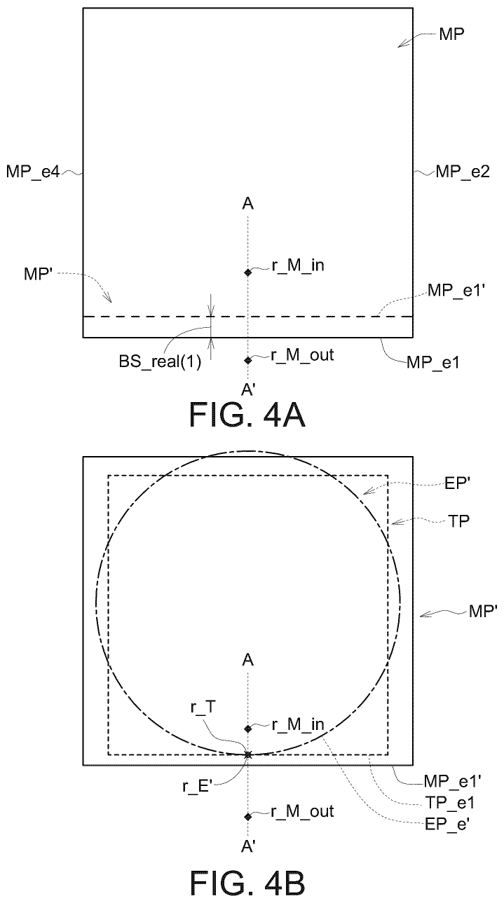

FIG. 4A is a schematic diagram showing the mask pattern MP is adjusted according to the actual offset BS_real(1). As shown in FIG. 4A, taking the mask pattern MP as an example, the currently processed edge is the edge MP_e1, and the mask pattern correcting unit 400 calculates the actual offset BS_real(1).

The mask pattern generating unit 100 adjusts the mask pattern MP according to the actual offset BS_real(1), and shifts the edge MP_e1 of the mask pattern MP by the actual offset BS_real(1) along the direction of the reference line AA′. The shifted edge MP_e1, which is shifted according to the actual offset BS_real(1), forms an adjusted edge MP_e1′. The mask pattern generating unit 100 generates an adjusted mask pattern MP′ according to the adjusted edge MP_e1′, and the mask pattern generating unit 100 provides the adjusted mask pattern MP′ to the developing system 2000 for further exposure and development.

FIG. 4B is a schematic diagram showing the developing system 2000 performs further exposure and development according to the adjusted mask pattern MP′. As shown in FIG. 4B, the developing system 2000 performs exposure and development again according to the adjusted mask pattern MP′, so as to generate an adjusted development pattern EP′. After adjustment, the periphery EP_e′ of the adjusted development pattern EP′ is close to the edge TP_e1 of the target pattern TP. In other words, an intersection (i.e., the new reference point r_E′) of the edge EP_e′ of the adjusted development pattern EP′ and the reference line AA′ is close to (or even overlaps with) the intersection of the edge TP_e1 of the target pattern TP and the reference line AA′ (i.e., the reference point r_T).

On the other hand, if there is still a distance between the new reference point r_E′ of the periphery EP_e′ of the adjusted development pattern EP′ and the reference point r_T of the edge TP_e1 of the target pattern TP, the operating device 1000 will perform a next iteration of optical proximity correction according to the new reference point r_E′.

In the next iteration, the light intensity analyzing unit 300 analyzes the light intensity I_{E}′ of the new reference point r_E′. Furthermore, the mask pattern correcting unit 400 substitutes the light intensity I_{E}′ into equation (1-1) to calculate the preliminary offset BS′(1) for the next iteration. The preliminary offset BS′(1) of the next iteration corresponds to the edge MP_e1′ of the adjusted mask pattern MP′.

Then, the mask pattern correcting unit 400 substitutes the preliminary offset BS′(1) of the next iteration into equations (2-1) to (2-3) to calculate the actual offset BS_real′(1) of the next iteration. The mask pattern generating unit 100 further adjusts the adjusted mask pattern MP′ according to the actual offset BS_real′(1) of the next iteration.

In summary, the optical proximity correction performed by the operating device 1000 of the present disclosure considers the optical characteristics of the development pattern EP. The light intensity analyzing unit 300 analyzes the light intensity distribution I(EP) associated with the development pattern EP, so as to further obtain the light intensity Iᵢₙ of the reference point r_M_in, the light intensity Iₒᵤₜ of the reference point r_M_out, the light intensity I_{T} of the reference point r_T, and the light intensity I_{E} of the reference point r_E. Furthermore, the mask pattern correcting unit 400 calculates the preliminary offset BS(n), which should be adjusted for the currently processed edge (for example, edge MP_e1) of the mask pattern MP, according to the above-mentioned light intensities Iᵢₙ, Iₒᵤₜ, I_{T} and I_{E}. Since the light intensity distribution I(EP) associated with the development pattern EP is taken into consideration, the value of the preliminary offset BS(n) can be estimated more accurately.

In addition, when calculating the actual offset BS_real(n) finally determined for the currently processed edge (e.g., edge MP_e1), the influence of the adjacent edges of the currently processed edge is also taken into consideration. The third weight W3 is calculated according to the offset weighted sum BS_SUM of the respective adjacent edges (such as equation (2-1)), so as to perform a weighted product on the preliminary offset BS(n) of the currently processed edge and obtain the actual offset BS_real(n) of the currently processed edge. Since the actual offset BS_real(n) of the current processing edge considers the influence of the offset(s) of the adjacent edge(s), the mask pattern MP can be more appropriately adjusted according to the actual offset BS_real(n), such that the corresponding development pattern EP is closer to the target pattern TP. The operating device 1000 of the present disclosure can obtain a development pattern EP which is closest to the target pattern TP, with fewer iterations, and hence the optical proximity correction performed by the operating device 1000 may have a faster convergence speed.

On the other hand, the optical proximity correction performed by the operating device 1000 of the present disclosure is compared with a comparative example. This comparative example uses traditional optical proximity correction of using the “BSL convergence” algorithm, which calculates the offset BS(n) to be adjusted for the current processing edge of the mask pattern MP according to the linear distance epe(n) between the target edge reference point r_T and the development periphery reference point r_E and the magnification meef(n), as shown in equation (3-1):

$$BS ( n ) = \frac{e p e ( n )}{meef ( n )} \qquad ( 3 - 1 )$$

The traditional “BSL convergence” algorithm only considers the parameters of the currently processed edge of the mask pattern MP, but does not consider the influence of the offset(s) of the adjacent edge(s). Therefore, the estimation accuracy of the offset BS(n) is low, resulting in low adjustment efficiency of the mask pattern MP. Moreover, the “BSL convergence” algorithm requires more times of iterations, and hence converges more slowly.

In contrast, compared to the traditional “BSL convergence” algorithm, the optical proximity correction performed by the operating device 1000 of the present disclosure considers the light intensity distribution I(EP) associated with the development pattern EP, and takes into account the offset weighted sum BS_SUM of adjacent edges, thereby improving the estimation accuracy of the offset BS(n). Furthermore, the convergence speed of iterations may hence be enhanced.

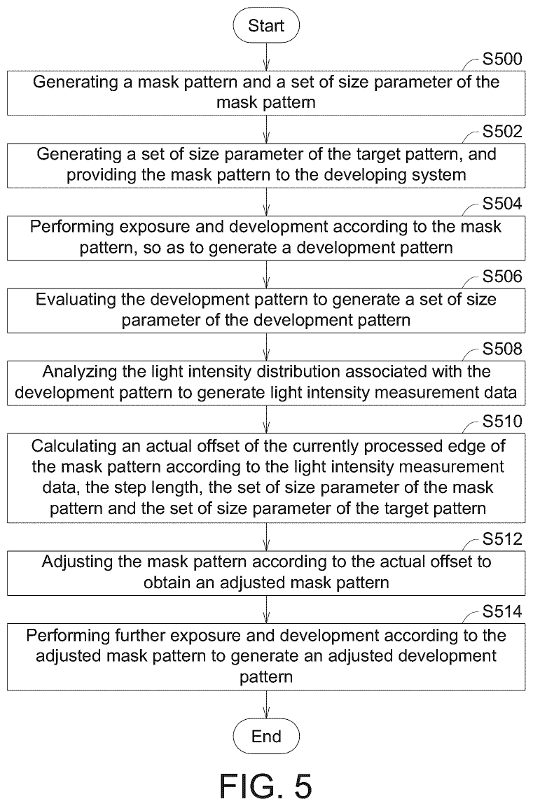

FIG. 5 is a flow diagram of an operating method according to an embodiment of the present disclosure. The operating method of this embodiment can be implemented by the operating device 1000 in FIG. 1. As shown in FIG. 5, firstly, step S500 is performed: the mask pattern generating unit 100 generates a mask pattern MP and a set of size parameter L(MP) of the mask pattern MP. Next, step S502 is performed: a set of size parameter L(TP) of the target pattern TP is generated by the mask pattern generating unit 100, and the mask pattern L(TP) is provided to the developing system 2000.

Next, step S504 is performed: the developing system 2000 performs exposure and development according to the mask pattern MP, so as to generate a development pattern EP. Next, step S506 is performed: the development pattern evaluating unit 200 evaluates the development pattern EP, so as to generate a set of size parameter L(EP) of the development pattern EP.

Next, step S508 is executed: the light intensity analyzing unit 300 analyzes the light intensity distribution I(EP) associated with the development pattern EP, so as to generate light intensity measurement data I_dat. The light intensity measurement data I_dat includes the light intensity Iᵢₙ of the mask interior reference point r_M_in, the light intensity Iₒᵤₜ of the mask exterior reference point r_M_out, the light intensity I_{T} of the target edge reference point r_T and the light intensity I_{E} of the development periphery reference point r_E.

More specifically, the mask interior reference point r_M_in and the mask exterior reference point r_M_out are respectively located inside and outside the currently processed edge (e.g., edge MP_e1) of the mask pattern MP, and a reference line AA′ is defined according to the mask interior reference point r_M_in and the mask exterior reference point r_M_out.

The target edge reference point r_T is an intersection of the reference line AA′ and the first edge of the target pattern TP (for example, edge TP_e1), and the first edge corresponds to the currently processed edge of the mask pattern MP. Furthermore, the development periphery reference point r_E is an intersection of the reference line AA′ and the periphery EP_e of the development pattern EP.

Next, step S510 is executed: the mask pattern correcting unit 400 calculates the actual offset BS_real(n) of the currently processed edge of the mask pattern MP according to the light intensity measurement data I_dat, the step length STP, the set of size parameter L(MP) of the mask pattern MP and the set of size parameter L(TP) of the target pattern TP.

More specifically, the step length STP is a distance between the mask exteriorl reference point r_M_out and the mask interior reference point r_M_in. The actual offset BS_real(n) is equal to a product of the preliminary offset BS(n) of the currently processed edge of the mask pattern MP and the third weight W3, as shown in equation (2-4). The preliminary offset BS(n) is equal to a product of the step length STP, the first weight W1 and the second weight W2, as shown in equation (1-1). The first weight W1 is equal to a ratio

$$( \frac{( {I}_{E} - {I}_{T} )}{\vert {I}_{i n} - {I}_{o u t} \vert} )$$

of the light intensity difference (I_{E}−I_{T}) between the development periphery reference point r_E and the target edge reference point r_T with respect to an absolute light intensity difference |Iᵢₙ−Iₒᵤₜ| between the mask interior reference point r_M_in and the mask exterior reference point r_M_out, as shown in equation (1-2). The second weight W2 is equal to a square of a ratio

$${( \frac{{L}_{T 1}}{{L}_{M 1}} )}^{2}$$

of the length L_{T1} of the first edge of the target pattern TP with respect to the length L_{M1} of the currently processed edge of the mask pattern MP, as shown in formula (1-3). The set of size parameter L(MP) of the mask pattern MP includes the length L_{M1} of the currently processed edge, and the set of size parameter L(TP) of the target pattern TP includes the length LT1 of the first edge of the target pattern TP. The third weight W3 is equal to a ratio

$$( \frac{BS\_SUM}{\vert BS ( n ) \vert} ) or ( \frac{\vert BS ( n ) \vert}{BS\_SUM} )$$

of the offset weighted sum BS_SUM with respect to the absolute value of the preliminary offset BS(n), or the third weight is equal to “1”. Moreover, the offset weighted sum BS_SUM is equal to an absolute value of the offset weighted sum of several adjacent edges of the currently processed edge, as shown in equation (2-1).

Next, step S512 is executed: the mask pattern generating unit 100 adjusts the mask pattern MP according to the actual offset BS_real(n), so as to obtain an adjusted mask pattern MP′. Next, step S514 is executed: the developing system 2000 performs exposure and development again, according to the adjusted mask pattern MP′, so as to generate an adjusted development pattern EP′.

It will be apparent to those skilled in the art that various modifications and variations can be made to the disclosed embodiments. It is intended that the specification and examples be considered as exemplars only, with a true scope of the disclosure being indicated by the following claims and their equivalents.

What is claimed is:

1. An operating device, for an optical proximity correction of a mask pattern, the operating device comprising:
a mask pattern generating unit, for generating the mask pattern and a set of size parameters of the mask pattern, and generating a set of size parameters of a target pattern, and providing the mask pattern to a developing system, and the developing system performs exposure and development according to the mask pattern to generate a development pattern;
a development pattern evaluating unit, for evaluating the development pattern to generate a set of size parameters of the development pattern;
a light intensity analyzing unit, for analyzing a light intensity distribution associated with the development pattern to generate a light intensity measurement data; and
a mask pattern correcting unit, for calculating an actual offset of a currently processed edge of the mask pattern according to the light intensity measurement data, a step length, the set of size parameters of the mask pattern and the set of size parameters of the target pattern, wherein the step length is a distance between a mask exterior reference point and a mask interior reference point,
wherein the mask pattern generating unit adjusts the mask pattern according to the actual offset to obtain an adjusted mask pattern, and the developing system performs exposure and development again according to the adjusted mask pattern to generate an adjusted development pattern.

2. The operating device of claim 1, wherein the light intensity measurement data comprises a light intensity of the mask interior reference point, a light intensity of the mask exterior reference point, a light intensity of a target edge reference point and a light intensity of a development periphery reference point.

3. The operating device of claim 2, wherein the mask interior reference point and the mask exterior reference point are respectively located on an inside and an outside of the currently processed edge of the mask pattern, and a reference line is defined according to the mask interior reference point and the mask exterior reference point.

4. The operating device of claim 3, wherein the target edge reference point is an intersection of the reference line and a first edge of the target pattern, the first edge corresponds to the currently processed edge of the mask pattern, and the development periphery reference point is an intersection of the reference line and a periphery of the development pattern.

5. The operating device of claim 4, wherein a preliminary offset of the currently processed edge of the mask pattern is equal to a product of the step length, a first weight and a second weight, and the actual offset is equal to a product of the preliminary offset and a third weight.

6. The operating device of claim 5, wherein the first weight is equal to a ratio of a light intensity difference between the development periphery reference point and the target edge reference point with respect to an absolute light intensity difference between the mask interior reference point and the mask exterior reference point.

7. The operating device of claim 5, wherein the second weight is equal to a square of a ratio of a length of the first edge of the target pattern with respect to a length of the currently processed edge of the mask pattern.

8. The operating device of claim 7, wherein the set of size parameters of the mask pattern comprise the length of the currently processed edge of the mask pattern, and the set of size parameters of the target pattern comprise the length of the first edge of the target pattern.

9. The operating device of claim 5, wherein the third weight is equal to a ratio of an offset weighted sum with respect to an absolute value of the preliminary offset, or the third weight is equal to “1”.

10. The operating device of claim 9, wherein the offset weighted sum is equal to an absolute value of a weighted sum of respective offsets of a plurality of adjacent edges of the currently processed edge.

11. An operating method, for an optical proximity correction of a mask pattern, the operating method comprising:
generating the mask pattern and a set of size parameters of the mask pattern, by a mask pattern generating unit;
generating a set of size parameters of a target pattern by the mask pattern generating unit, and providing the mask pattern to a developing system;
performing exposure and development by the development system according to the mask pattern to generate a development pattern;
evaluating the development pattern to generate a set of size parameters of the development pattern, by a development pattern evaluating unit;
analyzing a light intensity distribution associated with the development pattern to generate a light intensity measurement data, by a light intensity analyzing unit;
calculating an actual offset of a currently processed edge of the mask pattern according to the light intensity measurement data, a step length, the set of size parameters of the mask pattern and the set of size parameters of the target pattern by a mask pattern correcting unit, wherein the step length is a distance between a mask exterior reference point and a mask interior reference point;
adjusting the mask pattern according to the actual offset by the mask pattern generating unit, so as to obtain an adjusted mask pattern; and
performing exposure and development again according to the adjusted mask pattern by the developing system, so as to generate an adjusted development pattern.

12. The operating method of claim 11, wherein the light intensity measurement data comprises a light intensity of the mask interior reference point, a light intensity of the mask exterior reference point, a light intensity of a target edge reference point and a light intensity of a development periphery reference point.

13. The operating method of claim 12, wherein the mask interior reference point and the mask exterior reference point are respectively located on an inside and an outside of the currently processed edge of the mask pattern, and a reference line is defined according to the mask interior reference point and the mask exterior reference point.

14. The operating method of claim 13, wherein the target edge reference point is an intersection of the reference line and a first edge of the target pattern, the first edge corresponds to the currently processed edge of the mask pattern, and the development periphery reference point is an intersection of the reference line and a periphery of the development pattern.

15. The operating method of claim 14, wherein a preliminary offset of the currently processed edge of the mask pattern is equal to a product of the step length, a first weight and a second weight, and the actual offset is equal to a product of the preliminary offset and a third weight.

16. The operating method of claim 15, wherein the first weight is equal to a ratio of a light intensity difference between the development periphery reference point and the target edge reference point with respect to an absolute light intensity difference between the mask interior reference point and the mask exterior reference point.

17. The operating method of claim 15, wherein the second weight is equal to a square of a ratio of a length of the first edge of the target pattern with respect to a length of the currently processed edge of the mask pattern.

18. The operating method of claim 17, wherein the set of size parameters of the mask pattern comprise the length of the currently processed edge of the mask pattern, and the set of size parameters of the target pattern comprise the length of the first edge of the target pattern.

19. The operating method of claim 15, wherein the third weight is equal to a ratio of an offset weighted sum with respect to an absolute value of the preliminary offset, or the third weight is equal to “1”.

20. The operating method of claim 19, wherein the offset weighted sum is equal to an absolute value of a weighted sum of respective offsets of a plurality of adjacent edges of the currently processed edge.
